(19) United States
(12) Patent Application Publication
(10) Pub. No.: US 2026/0194582 A1
(43) Pub. Date: Jul. 9, 2026

(54) METHOD AND DEVICE FOR PROVIDING A RELAXATION MODEL FOR VOLTAGE PREDICTION DURING RELAXATION OF A DEVICE BATTERY FOR DETERMINING A CHARGING STATE

(71) Applicant: Robert Bosch GmbH, Stuttgart (DE)

(72) Inventors: Christoph Woll, Gerlingen (DE); Christian Simonis, Leonberg (DE); Gunther Handte, Unterensingen (DE)

(21) Appl. No.: 19/440,793

(22) Filed: Jan. 6, 2026

(30) Foreign Application Priority Data
Jan. 7, 2025 (DE) 10 2025 100 280.0

(51) Int. Cl. G01R 31/367; G01R 31/374; G01R 31/385

(52) U.S. Cl. CPC G01R 31/367; G01R 31/374; G01R 31/385

(57) ABSTRACT

Computer-implemented methods for determining a start charging state of a device battery (41) of a technical device (4) after a shutdown phase. One example includes upon determining a shutdown of the technical device (S1), providing (S2) recently detected operational variable profiles of operational variables of the device battery; modeling (S3) a terminal voltage profile and a charging state profile after a shutdown time of the technical device using a parameterized electrochemical battery model; providing (S4) the terminal voltage profile and the charging state profile in a battery controller of the device battery; upon detecting a switch-on of the technical device (S5), measuring (S6) a terminal voltage at a switch-on time; and providing (S8, S9) the charging state of the modeled charging state profile for the switch-on time as the start charging state.

### BACKGROUND

The invention relates to device batteries and in particular to methods for determining a model value of a terminal voltage of the device battery. The invention further relates to methods for using a relaxation model to determine a precise value of a charging state.

Knowledge of the current battery charging state is essential in numerous battery-powered applications, such as electric vehicles. However, a majority of the devices are not continuously operated and there are operational breaks during which no information about the device battery is available that enables a precise indication of a current charging state value. Determining the current charging state when switching on the technical device is therefore usually difficult.

Methods are known in the prior art with which the value of the charging state can be determined during or after the relaxation phase, so that the determination of the start charging state can be as precise as possible when the technical device is started/switched on. These methods utilize voltage values from the battery cells measured when the technical device is switched off/shut down and determine the start charging state when the device is switched on based on the model. However, when starting/switching on the device, deviations may occur between the then measured voltage values and the modeled voltage values indicative of a mismatch of the underlying model and requiring model correction, if necessary.

Generally, during an operational phase, the profile of the charging state can be tracked very precisely by integrating supplied and withdrawn electrical energy. However, it is important to know the start charging state when the technical device is switched on after the technical device has been switched off for a period of time.

### SUMMARY

According to the invention, a method for providing a charging state of a device battery, in particular after a restart after a shutdown phase, as well as a corresponding device according to the disclosure are provided.

According to a first aspect, an at least partially computer-implemented method for determining a start charging state of a device battery of a technical device after a shutdown phase is provided, with the following steps:
upon determining a shutdown of the technical device, providing recently detected operational variable profiles of operational variables of the device battery;
modeling a terminal voltage profile and a charging state profile for a period of time after a shutdown time of the technical device using a parameterized electrochemical battery model;
providing the terminal voltage profile and the charging state profile in a battery controller of the device battery;
upon detecting a switch-on of the technical device, measuring a terminal voltage at a switch-on time;
providing the state of charge of the modeled charging profile for the switch-on time as the start charging state depending on the result of a comparison of the measured terminal voltage and the modeled terminal voltage at the switch-on time.

Device batteries are electrochemical energy stores having a specific electrochemistry. The substances present in the device battery change when unpowered, and even if a chemical balance has been established in the device battery, changes in the internal conditions and compositions take place.

The above method is generally based on using operational variables, which are detected up to a shutdown of a battery-operated device, to determine a start value of the charging state of the device battery present at the time the technical device is switched on. Determining this start charging state is model-based, and the method further allows for correction of a corresponding electrochemical battery model.

Missing operational variables of a device battery outside of the actual operation of the technical device result in inaccuracies in the model calculations, such as voltage prediction, and determination of the associated determination of a charging state value. Conversely, if operational variables are still detected after switching off the technical device, advantages for the calculations of the model and for determining the charging state at a time of switching on the technical device result.

After operating the technical device, the device battery enters a relaxation phase in which the terminal voltage changes. The terminal voltage increases after a discharging operation, and decreases after a charging operation. Thereby, a change of the charging state value determined based on the terminal voltage is also associated. So far, no determination of the charging state value takes place during the relaxation phase, i.e. changes in the charging state during this time are not taken into account.

At the time the device is started/switched on, the battery voltage is measured. This value corresponds almost to the open-circuit voltage (U_ocv). The deviation from the actual open-circuit voltage, if the switch-on occurs during the active relaxation phase, results from the fact that in the course of the relaxation phase—even when there is no external voltage on the battery and no current flows—lithium ions deposit in the graphite of the anode (after the discharging process, whereby the battery voltage increases and the SoC increases) or move away from the anode (after the charging process, thereby decreasing the battery voltage and the SoC), and thus no defined steady open-circuit state of the battery is present, which allows a precise determination of a value of a charging state based on the measured value of the neutral terminal voltage. The charge flow is greater at the start of the relaxation phase than in the further course, i.e. decreases during the relaxation phase until it transitions to a saturation state (balance state) at the end of the relaxation phase and the charge balance between anode and cathode or vice versa becomes zero. Only from this point in time, which is also strongly temperature-dependent, can the charging state value be precisely determined based on the terminal voltage.

This inaccuracy in the charging state determination is conventionally balanced using a weighting factor depending on the most recently stored charging state value prior to switching off the device and battery temperature. Since the load behavior prior to switching off the device also affects the voltage profile and thus the charging state value during the relaxation phase, this procedure leads to an incorrect determination of the start charging state after a shutdown phase.

If the start of the device occurs after the fully completed relaxation phase, the charging state value is determined based on the terminal voltage measured at the start time using the neutral voltage characteristic curve (OCV-SOC characteristic curve). This SoC value determination is very precise, as it is performed in the steady state and is determined by the battery cell manufacturers in extensive measurements prior to SoP, taking into account the relevant dependencies, and is stored on the battery controller in the form of characteristic curves or lookup tables. As the OCV-SOC characteristic curves continue to depend on the aging state, which can only be determined inaccurately in the battery controller, the determination of the start charging state is only inaccurately possible with this procedure.

The possibility of using a central processing unit remote from a device to evaluate operational variable data can result in opportunities to determine the start charging state more precisely.

According to the present invention, there is provided a method for determining a start charging state after a shutdown phase of a battery-powered technical device as well as a corresponding device according to the disclosure.

According to a first aspect, a computer-implemented method for determining a start charging state of a device battery of a technical device after a shutdown phase is provided, with the following steps:
upon determining a shutdown of the technical device, providing recently detected operational variable profiles of operational variables of the device battery;
modeling a terminal voltage profile and a charging state profile for a period of time after a shutdown time of the technical device using a parameterized electrochemical battery model;
providing the terminal voltage profile and the charging state profile in a battery controller of the device battery;
upon detecting a switch-on of the technical device, measuring a terminal voltage at a switch-on time;
providing the state of charge of the modeled charging profile for the switch-on time as the start charging state depending on the result of a comparison of the measured terminal voltage and the modeled terminal voltage at the switch-on time.

Furthermore, the operational variable profiles are provided in a remote central processing unit, wherein the terminal voltage profile and the state of charge profile are modeled in the central processing unit for a period of time after the shutdown time and subsequently transmitted back to the technical device.

The above method provides for a determination of the start charging state based on an electrochemical battery model that can always be readjusted once it is determined that the electrochemical battery model does not match the conditions of the device battery. To this end, the technical device may be in communication with a central processing unit associated with a plurality of technical devices, which detects operational variable profiles relating to the device battery and always readjusts the underlying electrochemical battery model based on the operational variable profiles of a plurality of device batteries.

The above procedure now provides that the shutdown times or non-operational times, in which there is no current flow in the device battery and also no data transmission to the central processing unit, are used to determine a start charging state and a modeled start terminal voltage of the device battery at the time when the technical device is put back into operation or operated, and on the other hand, based on determining a deviation between the modeled start terminal voltage and a measured start terminal voltage, optionally perform a readjustment of the electrochemical battery model, with which the start charging state can be determined.

The method is preferably performed in the central processing unit. The method provides that upon determining a shutdown of the technical device, the operational variable profiles that have not yet been transmitted to the central processing unit are transmitted to it. These serve to execute the electrochemical battery model, with which model parameters can be re-parameterized or profiles of one or more operational variables can be predicted.

Such an electrochemical battery model can comprise a differential equation system which, based on differential equations parameterized via model parameters, models internal battery states, in particular equilibrium states and, if applicable, kinetic states, using a time integration method and provides a relationship between temporal operating variable profiles of the device battery, namely a battery current, a battery voltage, a battery temperature and a charging state of the device battery, and the internal battery state. Such electrochemical battery models are known, for example, from the publications US20220179009A1, US20220334191A1, US20220099743A1, US 2016/023,566, US 2016/023,567 and US 2020/150,185 An aging state can also be inferred from the internal battery states in a manner known in itself.

It may be provided that the terminal voltage profile and the state of charge profile are modeled only during the relaxation phase, and the attained values of the terminal voltage and state of charge after the relaxation phase are assumed to be constant up to the switch-on time, or the terminal voltage profile and charging state profile are modeled for a period beyond the relaxation phase.

Using the electrochemical battery model, it is then possible to model the temporal profile of the terminal voltage of the device battery and its state of charge based on the shutdown time of the technical device, depending on the model parameters of the battery model and the operating variable profiles of the battery current of 0 A and an assumed temperature. which reflects the relaxation phase and the subsequent equilibrium phase.

The battery model can use the charging state value recently determined at the time of shutdown, the battery temperature last determined at the time of shutdown, and the aging state as input values, and, based on these, continue to calculate the parameterized electrochemical battery model for a period of time. The period of time may comprise a duration in which a resumption of operation of the technical device is to be expected.

Alternatively, the period of time may comprise only the relaxation phase that lasts for a period of time until voltage saturation is achieved, i.e. the voltage change of the modeled terminal voltage is less than a predetermined threshold value of, for example, 0.05 mV/min. This criterion determines the end of the relaxation phase. The terminal voltage and the charging state then reached are assumed to be constant for a period of time subsequent thereto until the switch-on time.

Depending on the temperature and ageing status profile, this results in a terminal voltage profile and a state of charge profile for the device battery during the relaxation phase at a battery current of 0 A.

The modeled voltage and charging state profile during the relaxation phase is transmitted to the technical device as a relaxation model and stored there temporarily. The relaxation model may specify a modeled terminal voltage and a modeled charging state depending on a time elapsed since the battery was disconnected from the supply and on a battery temperature.

Because the battery controller is still in overrun for a few minutes after the technical device has been turned off, the battery controller is still ready to receive and store this historical data so that it is available at a switch-on time and can be used to indicate the start charging state.

When the technical device is restarted, the battery controller measures the terminal voltage and compares the measured terminal voltage with the terminal voltage modeled from the modeled voltage profile. As long as the measured voltage and the modeled terminal voltage are identical or only have a deviation within a tolerance range, the corresponding modeled charging state value is determined as the start charging state.

If, on the other hand, there is a deviation between both values of the terminal voltage, the measured terminal voltage value is trusted more than the modeled voltage value, excluding a possible error of the voltage sensors. The measured voltage value is assigned the charging state value corresponding to the modeled voltage value of the voltage profile during the relaxation phase.

If the difference between the measured and modelled terminal voltage is greater than a specified threshold value, not only can the measured terminal voltage value be transmitted to the central processing unit, but also the modelled terminal voltage value at the start time of the technical device. This may be used to readjust the electrochemical battery model by parameter variation (e.g., using a least square error method) so that all technical devices using the central processing unit may benefit from the improved electrochemical battery model. The improved battery model is then used as a basis for calculating the terminal voltage profiles after the switch-off time of other devices.

Furthermore, in the event of a deviation of the measured terminal voltage from the modeled terminal voltage at the switch-on time, a state of charge is assumed as the state of charge, resulting from the voltage value of the measured terminal voltage at the switch-on time, wherein the terminal voltage measured at the switch-on time is associated with a time point during the relaxation phase, to which the modeled terminal voltage corresponds to the terminal voltage measured at the switch-on time, wherein the equivalent charging state corresponds to the charging state from the charging state profile at the time thus determined.

It may be contemplated that, after switching off and prior to switching on the technical device, one or more measured terminal voltages are detected at different times, wherein the electrochemical battery model is re-parameterized or corrected with those measured terminal voltages that deviate from the corresponding modeled voltage value of the voltage profile by more than a predetermined threshold value.

According to one embodiment, a data-based correction model is created that provides a correction value with which the charging state is determined depending on an aging state and a battery temperature.

### BRIEF DESCRIPTION OF THE DRAWINGS

Embodiments are explained in greater detail below with reference to the accompanying drawings. Shown are:

FIG. 1 a schematic illustration of battery-operated vehicles, the battery controllers of which are in communication with a central processing unit, for determining a start charging state;

FIG. 2 a flow chart illustrating a method of operating the vehicle, in particular for determining a start charging state; and

FIG. 3 a profile of the terminal voltage of the vehicle battery before, during, and after a shutdown phase;

FIG. 4 the temporal profile of the modeled terminal voltage and the measurement of the terminal voltage at certain points in time during the relaxation phase; and

FIG. 5 shows a modeled correction value K as a function of the temperature and aging state features.

### DETAILED DESCRIPTION

In the following, the method according to the invention is described using vehicle batteries as device batteries in a plurality of motor vehicles as similar devices. An electrochemical battery model is implemented in an off-vehicle central processing unit and used to determine a terminal voltage profile and a charging state profile during a shutdown phase of the vehicle. The electrochemical battery model may be re-parameterized or re-trained in the central processing unit.

The above example is representative of a plurality of stationary or mobile devices with a network-independent energy supply, such as vehicles (electric vehicles, pedelecs, etc.), systems, machine tools, household appliances, IOT devices, and the like, which are connected via a corresponding communication connection (e.g., LAN, Internet) to an external central processing unit (cloud).

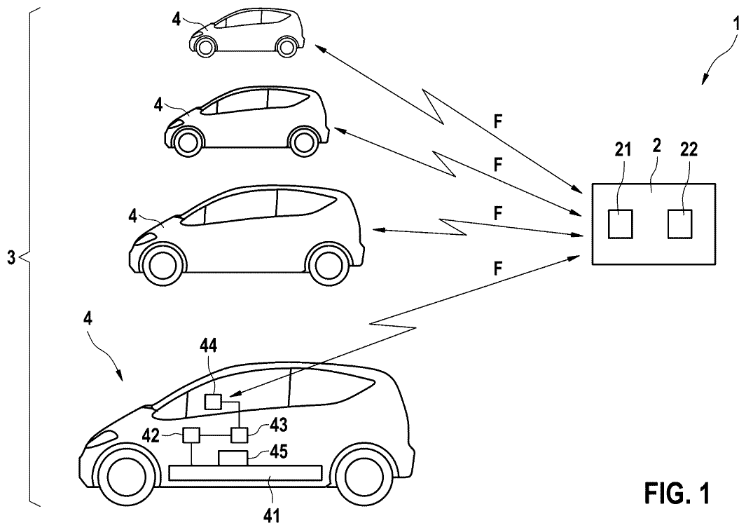

FIG. 1 shows a system 1 for collecting fleet data in a central processing unit 2 for creating and operating as well as evaluating an electrochemical battery model. The electrochemical battery model is used to determine a terminal voltage profile and a charging state profile of a vehicle battery in a motor vehicle based on provided temporal operational variable profiles 4, in particular the battery current and the battery temperature. FIG. 1 shows a vehicle fleet 3 with a plurality of motor vehicles 4, each connected to the central processing unit 2.

One of the motor vehicles 4 is shown in greater detail in FIG. 1. The motor vehicles 4 each have a vehicle battery 41 as rechargeable electric energy stores, an electric drive motor 42 and a controller 43. The controller 43 is connected to a communication device 44, which is suitable for transmitting data between the respective motor vehicle 4 and a central processing unit 2 (referred to as a cloud). Furthermore, a battery controller 45 may be provided that monitors the function of the vehicle battery 41 and continuously detects operational variables.

Using the communication module 44, the motor vehicles 4 transmit the operational variables F, which at least specify variables that characterize the battery state of the vehicle battery 41, to the central processing unit 2. In the case of a vehicle battery 41, the operating variables F can comprise time series of a battery current, a battery voltage, a battery temperature and a charging state (SOC: State of Charge), at the pack, module and/or cell level. The operating variables F are acquired in a fast chronological grid from 1 Hz to 100 Hz, and can be transmitted regularly to the central processing unit 2 in uncompressed and/or compressed form.

Furthermore, by using compression algorithms, the time series can be transmitted to the central processing unit 2 in blocks at intervals of several hours to several days in order to minimize data traffic to the central processing unit 2.

The central processing unit 2 has a data processing unit 21, in which the method described below can be carried out, and a database 22 for storing data points, model parameters, states and the like.

In the central processing unit 2, the electrochemical battery model is implemented, which, as a hybrid or semi-hybrid model, is data-based. The battery model may be evaluated periodically to determine current internal states of the relevant vehicle battery 41 based on the temporal profiles of the operational variables (in particular since commissioning the respective vehicle battery or since a last known battery state). Such an electrochemical battery model comprises a differential equation system which, based on differential equations parameterized via model parameters, models internal battery states, in particular equilibrium states and, if applicable, kinetic states, using a time integration method and provides a relationship between operating variables of the device battery, namely a battery current, a battery voltage, a battery temperature and a charging state of the device battery. Such electrochemical battery models are known, for example, from the publications US 2016/023,566, US 2016/023,567 and US 2020/150,185.

The electrochemical battery model is particularly suitable for this purpose and is adapted to model a corresponding profile of the terminal voltage and charging state based on the temporal profiles of a battery current and a battery temperature (depending on the specified model parameters of the battery model).

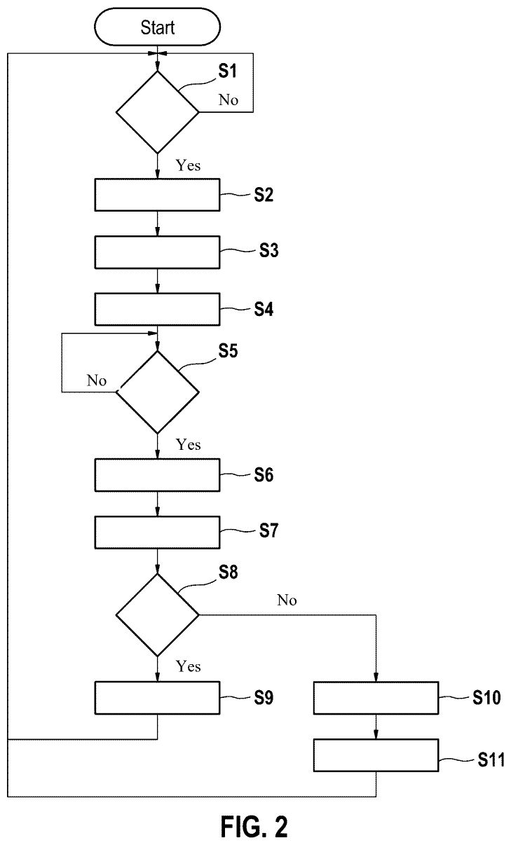

FIG. 2 shows a schematic illustration of a flowchart for illustrating the method for operating the vehicle. The method is performed in combination with the battery controller and the central processing unit.

In step S1, it is checked whether the vehicle 4 has been switched off. If this is the case (alternative: Yes), the method is continued with step S2, otherwise (alternative: No) the system jumps back to step S1.

In step S2, the most recently detected operational variable profiles are transmitted to the central processing unit 2.

In the central processing unit 2, voltage modeling is performed in step S3 based on the last detected operational variable profiles, a further assumed battery current of 0 A and a battery temperature that may correspond to the recently detected battery temperature or an ambient temperature derived from weather information. The voltage modeling is based on a predetermined electrochemical battery model implemented in the central processing unit 2.

The voltage profile and the charging state profile can be modeled until the relaxation phase is completed. This is the case if a gradient of the voltage change is less than 0.05 mV/min. Then, the achieved values of the terminal voltage and charging state are assumed to be constant up to the switch-on time. Alternatively, the voltage profile and the charging state profile may also be modeled for a longer period of time (longer than the relaxation phase) using the electrochemical battery model.

As a result of the modeling, there is a temporal voltage profile during and after a relaxation phase and a temporal profile of a charging state, which is equivalent to the modeled voltage, starting from the shutdown time.

In other words, the vehicle is stopped (terminal 15 off), so the data not yet transmitted to the central processing unit is transmitted to the central processing unit in the form of a data packet so that the battery model for voltage prediction has all the required input data, such as the last determined charging state, the terminal voltage, the battery temperature and the aging state. The electrochemical battery model generates a voltage profile for the phase of relaxation, which ends with the achievement of a voltage saturation (criterion: voltage change<threshold value).

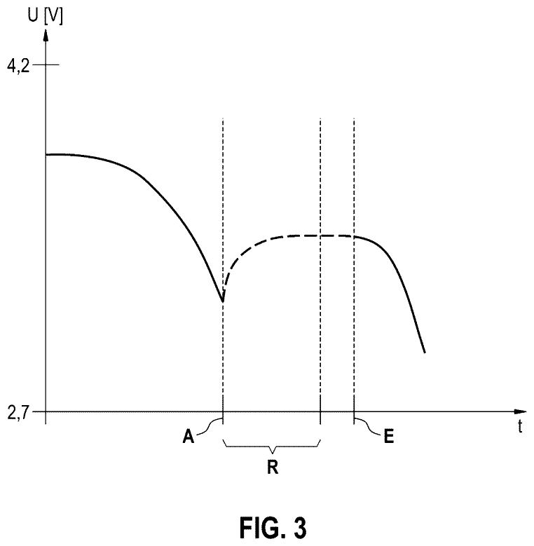

In FIG. 3, an exemplary profile of the terminal voltage before, during, and after a shutdown phase is shown. It can be seen that after an operational phase from the shutdown time A, the terminal voltage during a relaxation phase R increases to an equilibrium value and subsequently remains substantially constant. At a switch-on time E, the terminal voltage then decreases again due to the battery current flowing.

The voltage profile during the relaxation phase and the charging state profile equivalent to this can be transmitted back to the battery controller 43 in step S4. This transfer is usually carried out after the calculation substantially directly after the shutdown of the vehicle at the shutdown time. Furthermore, a relaxation model created in the central processing unit can be transmitted, indicating a relationship between the charging state and the terminal voltage (if necessary, temperature-dependent) so that an equivalent charging state can be assigned to a measured terminal voltage, if necessary, depending on the battery temperature.

Regardless of when the vehicle is restarted, the modeled and measured terminal voltage and the value of the charging state derived from the comparison result of both voltage values are thus present at the start time.

In step S5, it is checked whether the vehicle 4 is switched on. If a switch-on of the vehicle is detected (alternative: Yes), the method is continued with step S6; otherwise, it returns to step S5.

In step S6, the current terminal voltage of the vehicle battery 41 is measured using the battery controller 45.

In step S7, a modeled terminal voltage is determined based on the modeled voltage profile during and after the relaxation phase. Furthermore, at the switch-on time corresponding to the modeled charging state profile, a modeled start charging state is determined. This may be done based on the evaluation of the electrochemical battery model.

In step S8, the modeled terminal voltage is compared with the measured terminal voltage. If these match (taking into account a tolerance yield) (alternative: yes), in step S9 the modeled start charging state is determined as the actual start charging state. If it is determined that the modeled terminal voltage and the measured terminal voltage deviate from one another by more than one threshold amount (alternative: no), then in step S10 the start charging state is determined based on the measured terminal voltage. This may be done based on the temporal loading state profile and the temporal terminal voltage profile during the relaxation phase. The measured terminal voltage profile results in an equivalent profile of the charging state. The voltage at the start time determines the SOC at that time.

Moreover, in step S11, the electrochemical battery model may be re-parameterized, particularly based on the least square error method. The re-parameterization is carried out by transmitting the measured terminal voltage to the central processing unit 2 at the switch-on time, so that a re-parameterized electrochemical battery model can be used there to determine the next terminal voltage and charging state profiles during a relaxation phase. The re-parameterization should only take place if there is no sensor error of the current sensors and also otherwise no anomaly of the battery.

Further, the pre-parameterization of the electrochemical battery model may be based on a deviation between the measured terminal voltage and the modeled terminal voltage at the switch-on time.

The re-parameterization can also be based on a plurality of terminal voltages measured and modeled at the respective switch-on time of a plurality of vehicles, so that the database for parameter determinations of the electrochemical battery model is improved.

This method allows a precise determination of the start charging state and at the same time allows a re-parameterization of the electrochemical battery model. Readjustment or re-parameterization of the electrochemical battery model does not take place if the voltage measurement of the terminal voltage is incorrect or there are uncertainties about the value of the measured terminal voltage.

If data is also provided to the central processing unit 2 that is collected during inactivity of the vehicle 4, it can be used to compensate for inaccuracies in model calculations, such as voltage prediction and the charging state associated therewith. If, after stopping the vehicle 4 or switching off the device, data continues to be collected—possibly even at a higher sampling rate—and provided to the central processing unit 2, this results in advantages in the model calculations.

If terminal voltages are also used during the relaxation phase in the shutdown state of the vehicle, the re-parameterization can be performed in an improved manner, as there is a greater amount of data available for fitting the electrochemical battery model.

Thus, during the shutdown time, measurement data may still be determined, but at a higher sampling rate. To ensure that the duration for a data packet to reach its specified data size and be ready for transmission is reasonable in relation to the shutdown time or relaxation time, the data packets during this time must be smaller than during operating times of the vehicle (modified data packets). If the size is adjusted so that a data packet is transmitted every 10-15 min, this allows at least one data packet with current values of the central processing unit to be provided for evaluation, even with short shutdown times.

These data packets may comprise, among other things, the measured terminal voltage values (time profiles) of all cells. The determination of the predicted voltage profile during the relaxation phase may be preceded by a diagnosis that analyses the measured terminal voltages to determine whether;
a fault of a voltage sensor exists that leads to exclusion of this voltage signal for all further considerations;
individual measured voltage values of individual cells from which a temporal profile is generated have an anomaly such that these cells are not further considered for the evaluation and re-parameterization of the electrochemical battery model;
the modeled terminal voltage values differ too greatly from the measured terminal voltages of the cell having the lowest terminal voltage at the same sampling time, so that a model correction of the electrochemical battery model is required.

In case 3), a model correction/parameter adjustment for the electrochemical battery model is performed based on the measured voltage values and optionally the temperature values in order to determine the modeled voltage profile and the profile of the equivalent charging state in more detail as a result. Both profiles can be transmitted to the battery control unit 45 so that a precisely predicted voltage trajectory can always be determined there during the relaxation phase.

The adjustment of the battery model can occur with any determination of data during the shutdown phase and can repeat until the vehicle exits the inactive state or is started, respectively.

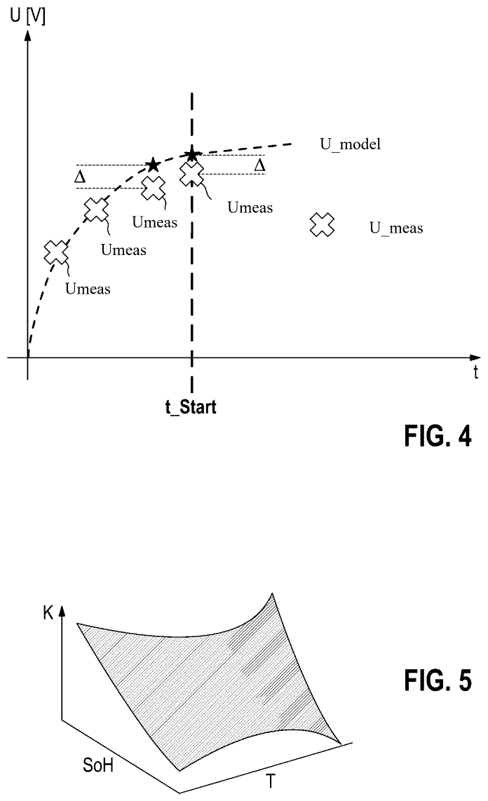

FIG. 4 shows the temporal profile of the modeled terminal voltage U_model (dashed) and the measurement of the terminal voltage U_meas (crosses) at certain points in time during the relaxation phase. The equivalent charging state is determined from the voltage value of the measured terminal voltage at the switch-on time, wherein the terminal voltage measured at the switch-on time t_Start is assigned a time during the relaxation phase, at which the modeled terminal voltage corresponds to the terminal voltage measured at the switch-on time t_Start, wherein the equivalent charging state corresponds to the charging state from the charging state profile at the time thus determined.

It may be provided that terminal voltages are only transmitted to the central processing unit if there is a difference between the voltage value of the most recently updated voltage profile and the currently measured voltage value.

The transmission of the voltage profile and the matching equivalent charging state is therefore required to be able to determine the matching equivalent charging state based on the measured voltage when there is a difference between the modeled and measured voltage.

In the central processing unit 2, the electrochemical battery model with voltage values can be parameterized during a relaxation phase of a plurality of similar batteries.

It may be provided that a global correction model is derived, which is trained as follows:
Input/features associated with the time of the last time series data measured in the vehicle before the vehicle is stopped:
   Aging state;
   Electrochemical features or parameters, such as cyclable lithium
   Ambient condition, in particular a battery temperature
   Charging state;
   as well as other electrochemical or physical variables, in particular cumulative quantities, such as Ah throughput
Label/target size of regression:
   Correction value of the SoC (or alternatively SoC_corrected absolute/relative or correction factor)

The correction model may be supervised trained which allocates a correction value to the measured charging state of all features present at the time of the last measured signal in the vehicle. Advantageously, the model is configured as a probabilistic model, in particular as a sparse Gaussian process, and uses training data from all correction operations ever performed in our process across all fleet participants, including all historical fleet data from the cloud. Other possible supervised learning models include neural networks, random forests, AdaBoost, or other data-based regression models.

FIG. 5 visualizes a modeled correction value K as a function of the battery temperature T and aging state SOH features.

Once the correction model has a certain grade in the central processing unit 2, the correction model can be implemented embedded in the vehicle. Advantageously, only model parameters are updated here. Thus, in the vehicle in operation, directly prior to parking/shutdown or in the event of connectivity loss, the model can be questioned and the output can be stored in the EPROM (Electrically Erasable Programmable Read-Only Memory) so that when the vehicle is activated, there is the best possible estimate of the charging state.

In an advantageous embodiment, the Gaussian process prediction is not only evaluated from the expected value, but rather a quantile-based evaluation, e.g., the 5% quantile, is performed. Thus, model uncertainty can be directly included, which is purely dependent on the input space, the data points available for training. This is helpful to indicate to the driver a realistic but not too optimistic range prediction, which is derived based on the charging state.

1. A computer-implemented method for determining a start charging state of a device battery of a technical device after a shutdown phase, the method comprising:
upon determining a shutdown of the technical device, providing recently detected operational variable profiles of operational variables of the device battery;
modeling a terminal voltage profile and a charging state profile for a period of time after a shutdown time of the technical device using a parameterized electrochemical battery model;
providing the terminal voltage profile and the charging state profile in a battery controller of the device battery;
upon detecting a switch-on of the technical device, measuring a terminal voltage at a switch-on time; and
providing the charging state of the modeled charging state profile for the switch-on time as the start charging state depending on the result of a comparison of the measured terminal voltage and the modeled terminal voltage at the switch-on time.

2. The method according to claim 1, wherein the terminal voltage profile and the charging state profile are modeled based on the last detected operational variable profiles of a further assumed battery current of 0 A and a battery temperature corresponding to the recently detected battery temperature or an ambient temperature derived from weather information.

3. The method according to claim 2, wherein the terminal voltage profile and the charging state profile are modeled only during the relaxation phase, and the attained values of the terminal voltage and charging state are assumed to be constant up to the switch-on time, or the terminal voltage profile and charging state profile are modeled for a period beyond the relaxation phase.

4. The method according to claim 1, wherein the operational variable profiles are provided in a remote central processing unit (2), wherein the terminal voltage profile and the charging state profile are modeled in the central processing unit (2) for a period of time after the shutdown time and subsequently transmitted back to the technical device.

5. The method according to claim 1, wherein the charging state of the modeled charging state profile is provided as the start charging state for the switch-on time when the measured terminal voltage substantially corresponds to the modeled terminal voltage at the switch-on time and wherein a charging state is provided as the start charging state that results depending on the measured terminal voltage.

6. The method according to claim 1, wherein the electrochemical battery model is re-parameterized or corrected if the measured terminal voltage deviates from the modeled terminal voltage by more than a predetermined threshold value at the switch-on time.

7. The method according to claim 1, wherein, in the event of a deviation of the measured terminal voltage from the modeled terminal voltage at the switch-on time, a charging state is assumed as the charging state, resulting from the voltage value of the measured terminal voltage at the switch-on time, wherein the terminal voltage measured at the switch-on time is associated with a time point during the relaxation phase, to which the modeled terminal voltage corresponds to the terminal voltage measured at the switch-on time, wherein the equivalent charging state corresponds to the charging state from of the charging state profile at the time thus determined.

8. The method according to claim 1, wherein after switching off and prior to switching on the technical device, one or more measured terminal voltages are detected at different times, wherein the electrochemical battery model is re-parameterized or corrected with those measured terminal voltages that deviate from the corresponding modeled voltage value of the voltage profile by more than a predetermined threshold value.

9. The method according to claim 1, wherein a data-based correction model is created that provides a correction value with which the charging state is determined depending on an aging state and a battery temperature.

10. A computer configured to determining a start charging state of a device battery of a technical device after a shutdown phase, by:
upon determining a shutdown of the technical device, providing recently detected operational variable profiles of operational variables of the device battery;
modeling a terminal voltage profile and a charging state profile for a period of time after a shutdown time of the technical device using a parameterized electrochemical battery model;
providing the terminal voltage profile and the charging state profile in a battery controller of the device battery;
upon detecting a switch-on of the technical device, measuring a terminal voltage at a switch-on time; and
providing the charging state of the modeled charging state profile for the switch-on time as the start charging state depending on the result of a comparison of the measured terminal voltage and the modeled terminal voltage at the switch-on time.

11. A non-transitory, machine-readable storage medium comprising instructions that, when executed by a computer, cause the computer to determine a start charging state of a device battery of a technical device after a shutdown phase, by:
upon determining a shutdown of the technical device, providing recently detected operational variable profiles of operational variables of the device battery;
modeling a terminal voltage profile and a charging state profile for a period of time after a shutdown time of the technical device using a parameterized electrochemical battery model;
providing the terminal voltage profile and the charging state profile in a battery controller of the device battery;
upon detecting a switch-on of the technical device, measuring a terminal voltage at a switch-on time; and
providing the charging state of the modeled charging state profile for the switch-on time as the start charging state depending on the result of a comparison of the measured terminal voltage and the modeled terminal voltage at the switch-on time.
